(19) United States
(12) Patent Application Publication
(10) Pub. No.: US 2020/0124675 A1
(43) Pub. Date: Apr. 23, 2020

(54) METHOD AND SYSTEM FOR DIRECT ESTIMATION OF EXACT POWER IN REAL-TIME

(71) Applicant: Samsung Electronics Co., Ltd., Suwon-si (KR)

(72) Inventors: Sagar BHARATHRAJ, Bangalore (IN); Shashishekara Parampalli ADIGA, Bangalore (IN); Krishnan S. HARIHARAN, Bangalore (IN); Ashish KHANDELWAL, Bangalore (IN); Rajkumar Subhash PATIL, Bangalore (IN); Mohan Kumar Singh VERMA, Bangalore (IN)

(73) Assignee: Samsung Electronics Co., Ltd., Suwon-si (KR)

(21) Appl. No.: 16/661,114

(22) Filed: Oct. 23, 2019

(30) Foreign Application Priority Data
Oct. 23, 2018 (IN) 201841039958
Oct. 22, 2019 (IN) 2018 41039958
Oct. 23, 2019 (KR) 10-2019-0132148

(51) Int. Cl. G01R 31/387; G01R 31/3842; G01R 31/367; H01M 10/48; H01M 10/42

(52) U.S. Cl. CPC G01R 31/387; G01R 31/3842; H01M 2010/4271; H01M 10/48; H01M 10/425; G01R 31/367

(57) ABSTRACT

A method of estimating an available power of a battery may include: receiving discharge data associated with the battery and a minimum voltage cut-off of the battery; determining one or more discharge curves based on the discharge data; estimating a model representing the one or more discharge curves; calculating a plurality of parameter values of the model at a plurality of time intervals; and estimating the available power of the battery based on the plurality of parameter values and the minimum voltage cut-off of the battery.

### CROSS-REFERENCE TO RELATED APPLICATIONS

This application claims the benefit under 35 USC § 119(a) of Korean Patent Application No. 10-2019-0132148 filed on Oct. 23, 2019 in the Korean Intellectual Property Office, Indian Provisional Patent Application No. 201841039958 filed on Oct. 23, 2018 in the Indian Patent Office, and Indian Patent Application No. 201841039958 filed on Oct. 22, 2019 in the Indian Patent Office, the entire disclosures of which are incorporated herein by reference for all purposes.

### BACKGROUND

### 1. Field

The following description is related to battery capacity prediction. More particularly, the following description is related to a method and system for estimating available power of a battery in real-time.

### 2. Description of Related Art

Electronic devices commonly use a power supply system including a battery that requires periodic recharging. The battery degrades due to usage and the passage of time, which leading to losses that are irreversible and reversible in nature. Thus, the useful, extractable power of the battery decreases over a period of time. Power estimation of the battery is of prime importance from a user's point of view, and it is therefore very important to accurately estimate exact power available from the battery using minimal data and computational expenses. However, most protocols presently available are computationally very expensive and predict only the state of health (SOH) of the battery through the state of charge (SOC) of the battery. Additionally, most algorithms are used to estimate the resistive losses (reversible losses), which form only a part of the total loss incurred in the power supply system. Thus, the prediction of the power loss from the power supply system is partial and incomplete.

Accordingly, there is a need for a simple protocol to estimate the exact available power of a battery, which provides complete information of available power by considering both reversible and irreversible losses.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

A method of estimating an available power of a battery includes: receiving discharge data associated with the battery and a minimum voltage cut-off of the battery; determining one or more discharge curves based on the discharge data; estimating a model representing the one or more discharge curves; calculating a plurality of parameter values of the model at a plurality of time intervals; and estimating the available power of the battery based on the plurality of parameter values and the minimum voltage cut-off of the battery.

The estimating of the available power of the battery may include: measuring a resistive loss value of the battery and a capacity loss value of the battery based on the plurality of parameter values and the minimum voltage cut-off of the battery; calculating a power loss value based on the resistive loss value and the capacity loss value; and estimating the available power of the battery based on the calculated power loss value.

The discharge data may be collected at a plurality of time instances.

The discharge data may include any one or any combination of any two or more of a voltage, a current, a voltage rate, and a capacity of the battery.

The model representing the one or more discharge curves may be determined by y=an·x^{bn}+cₙ, wherein aₙ, bₙ, and cₙ are the plurality of parameter values of the model at an nth time interval of the plurality of time intervals, y is either one of a time and a capacity, and x is a normalized voltage axis.

The model representing the one or more discharge curves may be proportional to a combination of aₙ, bₙ, and cₙ, and aₙ, bₙ, and cₙ are the plurality of parameter values of the model at an nth time interval of the plurality of time intervals.

The resistive loss value of the battery may be current dependent and the capacity loss value of the battery may be current independent.

The capacity loss value of the battery may be determined by cₙ-c₀ and the resistive loss value of the battery may be determined by

$${V}_{min} / ( 1 - {( - {c}_{n} / {a}_{n} )}^{\frac{1}{{b}_{n}}} ) ,$$

wherein Vₘᵢₙ is the minimum voltage cut-off of the battery, wherein c₀ is a first one of the plurality of parameter values at a 0^{th} time interval of the plurality of time intervals and cₙ is the first one of the plurality of parameter values of the model at an n^{th} time interval of the plurality of time intervals, wherein aₙ is a second one of the plurality of parameter values of the model at the n^{th} time interval, and wherein bₙ is a third one of the plurality of parameter values of the model at the n^{th} time interval.

The power loss value of the battery may be determined by

$$( {c}_{n} - {c}_{0} ) \{ {V}_{min} / ( 1 - {( - {c}_{n} / {a}_{n} )}^{\frac{1}{{b}_{n}}} ) \} ,$$

wherein cₙ is a first one of the plurality of parameter values of the model at an nth time interval of the plurality of time intervals, wherein c₀ is the first one of the plurality of parameter values of the model at 0th time interval of the plurality of time intervals, wherein Vₘᵢₙ is the minimum voltage cut-off of the battery, wherein aₙ is a second one of the plurality of parameter values of the model at the n^{th} time interval, and wherein bₙ is a third one of the plurality of parameter values of the model at the n^{th} time interval.

A battery management system to estimate an available power of a battery may include: a memory; and a processor coupled to the memory and configured to: receive discharge data associated with the battery and a minimum voltage cut-off of the battery; determine one or more discharge curves based on the discharging data; estimate a model representing the one or more discharge curves; calculate a plurality of parameter values of the model at a plurality of time intervals; and estimate the available power of the battery based on the plurality of parameter values and the minimum voltage cut-off of the battery.

The processor may be further configured to: measure a resistive loss value of the battery and a capacity loss value of the battery based on the plurality of parameter values and the minimum voltage cut-off of the battery; calculate a power loss value based on the resistive loss value and the capacity loss value; and estimate the available power of the battery based on the power loss value.

The discharge data may include any one or any combination of any two or more of a voltage, a current, a voltage rate, and a capacity of the battery.

The resistive loss value of the battery may be current dependent and the capacity loss of the battery may be current independent.

The model that represents the one or more curves may be determined by y=aₙ·x^{bn}+cₙ, wherein aₙ, bₙ, and cₙ are the plurality of parameter values of the model at an n^{th} time interval of the plurality of time intervals, y is either one of a time and a capacity, and x is a normalized voltage axis.

The model representing the one or more discharge curves may be proportional to a combination of aₙ, bₙ, and cₙ, wherein aₙ, bₙ, and cₙ are the plurality of parameter values of the model at an n^{th} time interval of the plurality of time intervals.

The capacity loss value of the battery may be determined by cₙ-c₀ and the resistive loss

$${V}_{min} / ( 1 - {( - {c}_{n} / {a}_{n} )}^{\frac{1}{{b}_{n}}} ) ,$$

value of the battery may be determined by wherein Vₘᵢₙ is the minimum voltage cut-off of the battery, wherein c₀ is a first one of the plurality of parameter values at a O^{th} time interval of the plurality of time intervals and cₙ is the first one of the plurality of parameter values of the model at an n^{th} time interval of the plurality of time intervals, wherein aₙ is a second one of the plurality of parameter values of the model at the n^{th} time interval, and wherein bₙ is a third one of the plurality of parameter values of the model at the n^{th} time interval.

The power loss value of the battery may be determined by

$$( {c}_{n} - {c}_{0} ) \{ {V}_{min} / ( 1 - {( - {c}_{n} / {a}_{n} )}^{\frac{1}{{b}_{n}}} ) \} ,$$

wherein cₙ is a first one of the plurality of parameter values of the model at an n^{th} time interval of the plurality of time intervals, wherein c₀ is the first one of the plurality of parameter values of the model at 0^{th} time interval of the plurality of time intervals, wherein Vₘᵢₙ is the minimum voltage cut-off of the battery, wherein aₙ is a second one of the plurality of parameter values of the model at the n^{th} time interval, and wherein bₙ is a third one of the plurality of parameter values of the model at the n^{th} time interval.

The discharge data may be collected at a plurality of time instances.

Other features and aspects will be apparent from the following detailed description, the drawings, and the claims.

### BRIEF DESCRIPTION OF THE DRAWINGS

FIG. 1 illustrates a block diagram of a conventional system for estimating available power of a battery.

FIG. 2 illustrates a block diagram of system for estimating available power of a battery, according to an embodiment.

FIG. 3A is a diagram illustrating examples of battery discharge curves considering degradation of a battery over a period of time.

FIG. 3B illustrates modified diagram of FIG. 3A, according to embodiments.

FIG. 4 is a flowchart illustrating a method for estimation of available power, according to an embodiment.

FIG. 5A illustrates prediction of sudden power loss using a conventional method based primarily on capacity loss.

FIG. 5B illustrates prediction of sudden power loss using a method based on resistive loss and capacity loss, according to an embodiment.

FIG. 6 illustrates prediction of failure/ fault analysis using an existing method and a method according to an embodiment.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Herein, it is noted that use of the term “may” with respect to an example or embodiment, e.g., as to what an example or embodiment may include or implement, means that at least one example or embodiment exists in which such a feature is included or implemented while all examples and embodiments are not limited thereto.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

The features of the examples described herein may be combined in various ways as will be apparent after an understanding of the disclosure of this application. Further, although the examples described herein have a variety of configurations, other configurations are possible as will be apparent after an understanding of the disclosure of this application.

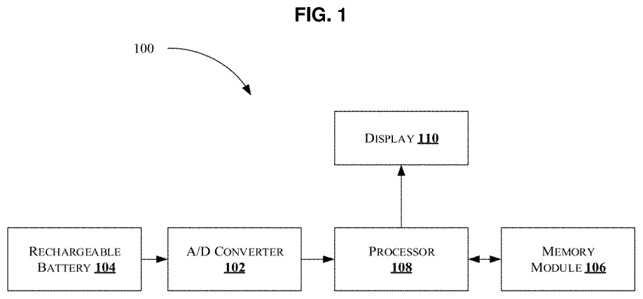

FIG. 1 illustrates one example of an apparatus 100 for determining an exact available power of a battery. The apparatus 100 may include an analog-to-digital (A/D) converter 102 that converts a voltage supplied by a rechargeable battery 104 into a digital voltage value signal, and a memory module 106 that stores data representing a single discharge curve corresponding to discharge characteristic value of the battery 104. The apparatus 100 may also include a processor 108 that determines available power of the battery 104 by comparing the voltage value signal from the A/D converter 102 to the single discharge curve stored in the memory module 106, and a display unit 110 that displays the determined available power of the battery 104 for viewing by a user.

In operation, when an electronic device using the apparatus 100 is activated, the electronic device initiates operation of the processor 108. The battery 104 supplies power to operate the electronic device, and the A/D converter 102 converts a voltage value measured across the battery 104 into a digital signal that is provided to the processor 108. The processor 108 compares the voltage value signal from the A/D converter 102 to a single battery discharge curve stored in the memory module 106 to determine the available power of the battery 104 corresponding to the measured discharge data. The processor 108 then sends the determined available power of the battery 104 to the display unit 110, and the display unit 110 displays the determined available power of the battery 104 for viewing by the user. Thus, the apparatus 100 notifies the user using a single discharge curve.

However, the single discharge curve fails to predict the actual available power due to degradation of battery over a period of time and unaccounted capacity losses, which are irreversible losses. For example, battery duration decreases in inverse proportion to the number of charge/discharge cycles occurring with repeated use of the battery. In addition, the output of the battery decreases more sharply as the battery residual capacity nears exhaustion during a given charge/discharge cycle. As a result, when the available power of the battery 104 is determined using a single, fixed discharge curve that represents both a new battery and a used battery, the available power of the battery 104 cannot always be accurately determined in accordance with the usage or state of the electronic device and the rechargeable battery. Thus, the result of the battery available power calculation excludes the effects of capacity losses of the battery, which sometimes results in display of an inaccurate available power of the battery 104 to the user. Consequently, the electronic device can abruptly and unexpectedly become inoperative because of a power shortage.

In an example implementation disclosed herein, an enhanced-accuracy battery capacity prediction apparatus uses multiple battery discharge curves that take into account either one or both of a plurality of discharge data of the battery during operation and the number of historical charge/discharge cycles the battery has undergone. In this manner, the remaining effective operational time, or available power of the battery 104 can be more accurately predicted at any given time or continuously during a charge/discharge cycle of the battery to provide more useful information and more accurate advanced warning of impending device inoperability to the electronic device user as the battery power is diminished and eventually becomes exhausted.

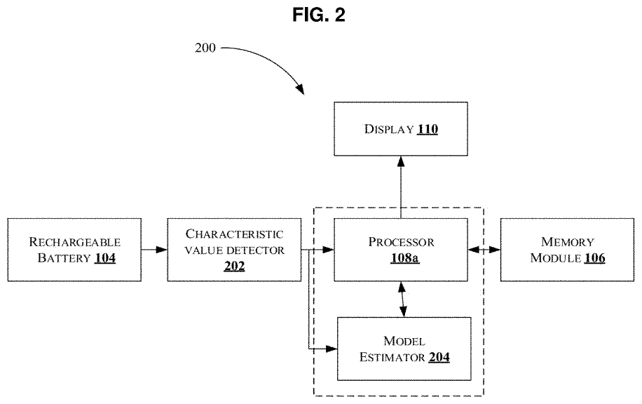

FIG. 2 illustrates an enhanced-accuracy battery capacity prediction apparatus 200 for detecting and displaying an exact available power of a battery 104, according to an embodiment. The apparatus 200 includes a characteristic value detector 202 that detects one or more characteristic values based on discharge data of a rechargeable battery 104 mounted in or operably connected to an electronic device, a memory module 106 that stores data corresponding to multiple discharge curves representing discharge characteristics of the battery 104 at a different time intervals, and a model estimator 204 that estimates a model that represents the multiple discharge curves. The apparatus 200 also includes a processor 108a that estimates available power of the battery 104, and the display device 110 that displays the available power of the battery 104 estimated by the processor 108a to a user.

The processor 108a estimates the available power of the battery 104 by computing a plurality of parameters of the model estimated at a plurality of time intervals using the model estimator 204 a resistive loss value and a capacity loss value of the battery 104 based on the plurality of parameters. The processor 108a computes a power loss value based on the measured resistive and capacity losses, and estimates the available power of the battery 104 based on the power loss value.

The characteristic values detected by characteristic value detector 202 can include, for example, electrical values associated with the battery 104, such as a voltage measured across the battery 104 or an electrical current supplied by the battery 104 to operate the electronic device. The characteristic values can also include, for example, other operational values associated with the battery 104, such as the number of historical charge/discharge cycles of the battery 104. The characteristic value detector 202 detects a characteristic value of the battery 104 when the electronic device performs a predetermined function. The characteristic value detector 202 also converts the detected characteristic value into a digital data format that can be processed by the processor 108a. For example, according to an example, the characteristic value detector 202 may include an A/D converter that converts an electrical current value supplied by the battery 104 into a digital signal. According to another example, the characteristic value detector 202 may include an A/D converter that converts a voltage measured across the battery 104 into a digital signal. Alternatively, the processor 108a may read or receive a characteristic value directly from the battery 104, from the memory module 106, or from another data source. For example, the number of recharges, or charge/discharge cycles, of the battery 104 may be used as a characteristic value representing the present status of the battery. Thus, if the battery 104 includes a memory device capable of storing predetermined information, the battery 104 may store information regarding the number of charge/discharge cycles of the battery 104 that can be read by the processor 108a.

The memory module 106 stores data corresponding to multiple discharge curves representing battery discharge characteristics. In an example, the memory module 106 includes nonvolatile memory, such as flash memory, that is capable of storing discharge curves even when power is disrupted, as well as random access memory (RAM) to temporarily store the discharge curves during the calculation process of the processor 108a. The discharge curves include data representative of various discharge characteristics of the rechargeable battery 104. For example, the discharge curves may map battery voltage, measured in Volts (V), to battery discharge capacity, measured in milliampere-hours (mAh). In addition, the discharge curves stored in the memory module 106 may represent multiple curves corresponding to various discharge rates, or rates of electric current supplied by the battery (which may be measured, for example, in milli amperes (mA)), so as to take into account the present usage or status of the electronic device. Furthermore, the discharge curves may represent multiple curves corresponding to varying numbers of charge/discharge cycles of the battery to take into account an overall life or a present performance status of the battery 104, the performance of which may be reduced over time. Additionally, the discharge curves may represent multiple curves corresponding to a combination of varying discharge rates and varying numbers of charge/discharge cycles to take into account both the present usage, or status, of the electronic device and the reduced performance of the rechargeable battery 104.

In some examples, the model estimator 204 and processor 108a may be separate modules executed by a central processing unit (not shown). The processor 108a may further control additional operations of the electronic device. The model estimator 204 estimates a unique model that represents multiple discharge curves which leads to a simple non-linear power-law profile, avoiding the need for the conventional many-order polynomial fits. The display 110 displays the available power of the battery 104 determined by the processor 108a. In various implementations, the display 110 may include a cathode ray tube (CRT) monitor, a liquid crystal display (LCD), a plasma display panel (PDP), or any other suitable display.

In operation, when system power of the electronic device is activated, the electronic device initiates operation under control of the central processing unit or processor 108a, for example, in response to a user input command. The battery 104 supplies power for operation of the device, and the characteristic value detector 202 detects a characteristic value of the battery 104, and supplies the detected characteristic value to the processor 108a as a digital data signal. The processor 108a uses the model estimator 204 to determine the available power of the battery 104 corresponding to the detected characteristic value. Once the available power of the battery 104 has been determined, the processor 108 communicates the available power to the display unit 110 for display for viewing by a user.

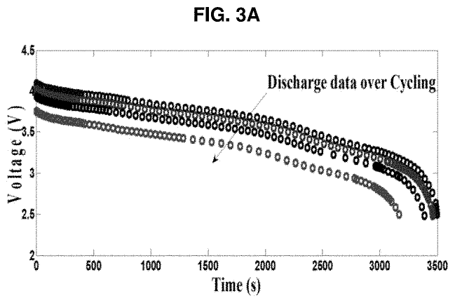

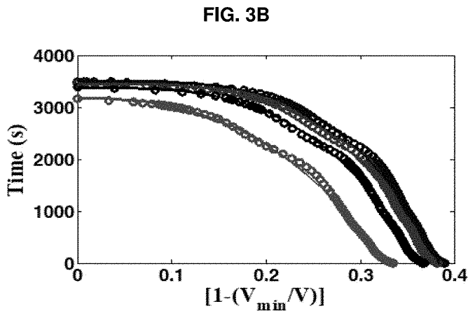

FIG. 3A is a diagram illustrating examples of battery discharge curves considering degradation of a battery (e.g. the battery 104) over a period of time.

FIG. 3B is the modified diagram of FIG. 3A. As shown in FIG. 3B, the horizontal axis represents a function of a ratio of Vₘᵢₙ and

$$V ( i . e . , 1 - \frac{{V}_{cut \text{-} off , min}}{V} ) ,$$

and the vertical axis represents either time or capacity. The model representing the plurality of discharge curves is estimated based on the plurality of discharge curves. In an embodiment, the model is represented as shown below in Equation 1, in which aₙ, bₙ, and cₙ represent the plurality of parameter values of the model at an n^{th} time interval, wherein n is an integer greater than or equal to 0.

y=aₙ·x^{bn}+cₙ [Equation 1]

In another embodiment, another model representing a simple non-linear power-law profile is used. Referring to FIG. 3B, the capacity loss as shown below in Equation 2 is computed when x=0 (i.e., at V=Vₘᵢₙ) and resistive loss as shown in below equation 3 is computed when y=0. The reversible resistive losses are current dependent and irreversible capacity losses are current independent.

capacity loss=C−C₀=(x=0 or V=Vₘᵢₙ) [Equation 2]

resistive loss=Vₘᵢₙ/{1−(−c/a)^{1/b}} [Equation 3]

The power loss is computed based on capacity loss and resistive loss as shown in below equation 4 and the available power of the battery 104 is computed based on the measured power loss.

Power loss=(C−C₀)Vₘᵢₙ/{1−(−c/a)^{1/b}} [Equation 4]

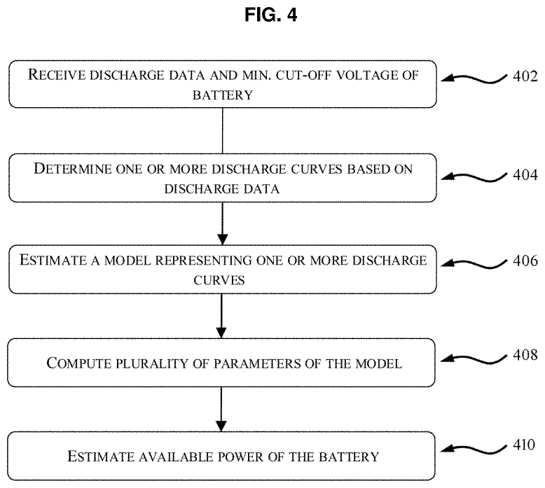

FIG. 4 is a flowchart illustrating a method for estimation of available power of a battery (e.g., the battery 104), according to an embodiment. Referring to FIG. 4, the method for estimation of available power of the battery 104 includes one or more operations or blocks for estimating available power of the battery 104.

The order in which the method of FIG. 4 is described is not intended to be constructed as a limitation, and any number of the described method blocks can be combined in any order to implement the method. Additionally, individual blocks may be deleted from the method without departing from the spirit and scope of the subject matter described herein. Furthermore, the method can be implemented in any suitable hardware, software, firmware, or combination thereof.

In operation 402, the min. cut-off voltage of the battery and discharge data associated with the battery 104 are received. According to an example, the discharge data includes any one or any combination of any two or more of a voltage, a current, a voltage rate, and a capacity of the battery 104. The discharge data is collected at a plurality of time instances.

In operation 404, the one or more discharge curves are determined based on the discharge data collected at the plurality of time instances. According to an example, data corresponding to the one or more discharge curve is stored in the memory module 106 associated with the electronic device.

In operation 406, a model representing the one or more discharge curves is estimated. In an example, the model representing the one or more discharge curves is represented by y=aₙ·x^{bn}+cₙ, and wherein aₙ, bₙ, and cₙ represent the plurality of parameter values of the model at nth time interval of the plurality of time intervals, y is the time or the capacity, and x is the normalized voltage axis

$$( x = 1 - \frac{{V}_{cut \text{-} off , min}}{V} ) .$$

In another example, the model representing the one or more discharge curves is represented by any other analytical equation.

In operation 408, the plurality of parameter values of the model are computed at a plurality of time intervals. In an example, aₙ, bₙ, and cₙ that represent the plurality of parameter values of the model at n^{th} time interval of the plurality of time intervals are computed.

In operation 410, the available power of the battery is estimated based on the computed plurality of parameter values and minimum voltage cut-off of the battery. In an example, resistive and capacity loss values of the battery are measured based on the plurality of parameter values and the minimum voltage cut-off the battery. In an example, resistive loss value of the battery is represented by (cₙ-c₀), wherein c₀ represents one of the plurality of parameter values at 0^{th} time interval of the plurality of time intervals. In an example, the capacity loss value of the battery is represented by

$${V}_{min} / ( 1 - {( - {c}_{n} / {a}_{n} )}^{\frac{1}{{b}_{n}}} ) ,$$

wherein Vₘᵢₙ is the minimum voltage cut-off of the battery. In an example, the power loss value is computed based on the resistive loss and capacity loss values, and estimating the available power of the battery based on the power loss values.

Thus, the disclosure herein estimates available power of the battery by using a unique representation of a discharge profile using a simple non-linear representation avoiding the need for conventional many-order polynomial fits and using a simple optimization tool to compute the parameters for the discharge profile, thereby reducing the need for heavy computations.

The estimated available power of the battery as determined herein may be used in many applications, such as predicting sudden loss of power and fault analysis.

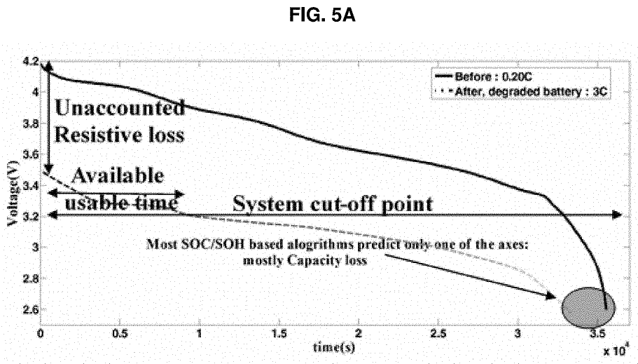

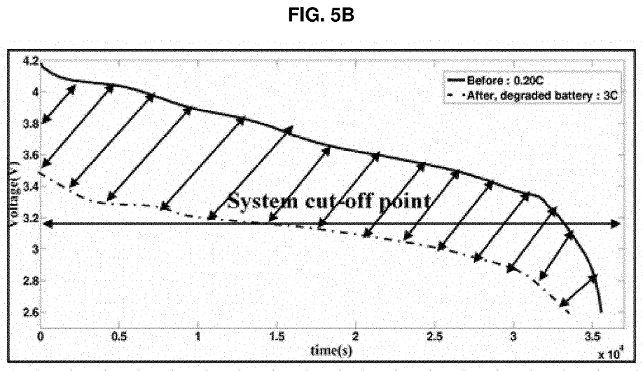

The main reason for sudden loss of power in systems in which power is supplied by a battery is the usage of power craving applications that drive the system to a higher C-rate regime. Normal algorithms as shown in FIG. 5A will fail to predict the actual loss due to degradation as most of these algorithms are SOC based algorithms estimating only the capacity loss. However, as shown in FIG. 5B, the method and system disclosed herein predict this actual power loss accounting for both resistive and capacity losses.

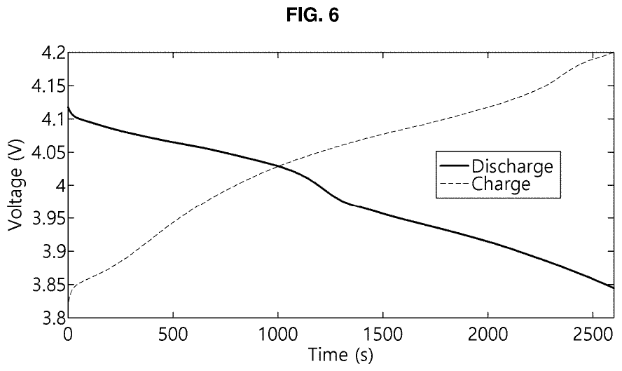

Additionally, existing methods and systems require a history of full charge-discharge information to predict power failure or to determine fault analysis information, whereas the disclosed method and system only need a small portion of the charge-discharge information, as shown in FIG. 6, to predict the power failure or to determine fault analysis information.

The memory module 106, the processors 108 and 108a, the characteristic value detector 202, and the model estimator 204 in FIGS. 1 and 2 that perform the operations described in this application are implemented by hardware components configured to perform the operations described in this application that are performed by the hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The method illustrated in FIG. 4 that performs the operations described in this application is performed by computing hardware, for example, by one or more processors or computers, implemented as described above executing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control a processor or computer to implement the hardware components and perform the methods as described above are written as computer programs, code segments, instructions or any combination thereof, for individually or collectively instructing or configuring the processor or computer to operate as a machine or special-purpose computer to perform the operations performed by the hardware components and the methods as described above. In one example, the instructions or software include machine code that is directly executed by the processor or computer, such as machine code produced by a compiler. In another example, the instructions or software include higher-level code that is executed by the processor or computer using an interpreter. Programmers of ordinary skill in the art can readily write the instructions or software based on the block diagrams and the flow charts illustrated in the drawings and the corresponding descriptions in the specification, which disclose algorithms for performing the operations performed by the hardware components and the methods as described above.

The instructions or software to control a processor or computer to implement the hardware components and perform the methods as described above, and any associated data, data files, and data structures, are recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

What is claimed is:

1. A method of estimating an available power of a battery, the method comprising:
receiving discharge data associated with the battery and a minimum voltage cut-off of the battery;
determining one or more discharge curves based on the discharge data;
estimating a model representing the one or more discharge curves;
calculating a plurality of parameter values of the model at a plurality of time intervals; and
estimating the available power of the battery based on the plurality of parameter values and the minimum voltage cut-off of the battery.

2. The method of claim 1, wherein the estimating of the available power of the battery comprises:
measuring a resistive loss value of the battery and a capacity loss value of the battery based on the plurality of parameter values and the minimum voltage cut-off of the battery;
calculating a power loss value based on the resistive loss value and the capacity loss value; and
estimating the available power of the battery based on the calculated power loss value.

3. The method of claim 1, wherein the discharge data is collected at a plurality of time instances.

4. The method of claim 1, wherein the discharge data comprises any one or any combination of any two or more of a voltage, a current, a voltage rate, and a capacity of the battery.

5. The method of claim 1, wherein the model representing the one or more discharge curves is determined by y=aₙ·x^{bn}+cₙ, and wherein aₙ, bₙ, and cₙ are the plurality of parameter values of the model at an n^{th} time interval of the plurality of time intervals, y is either one of a time and a capacity, and x is a normalized voltage axis.

6. The method of claim 1, wherein the model representing the one or more discharge curves is proportional to a combination of aₙ, bₙ, and cₙ, and wherein aₙ, bₙ, and cₙ are the plurality of parameter values of the model at an n^{th} time interval of the plurality of time intervals.

7. The method of claim 2, wherein the resistive loss value of the battery is current dependent and the capacity loss value of the battery is current independent.

8. The method of claim 7, wherein the capacity loss value of the battery is determined by cₙ-c₀, wherein the resistive loss value of the battery is determined by
$${V}_{min} / ( 1 - {( - {c}_{n} / {a}_{n} )}^{\frac{1}{{b}_{n}}} ) ,$$
wherein Vₘᵢₙ, is the minimum voltage cut-off of the battery, wherein c₀ is a first one of the plurality of parameter values at a 0^{th} time interval of the plurality of time intervals and cₙ is the first one of the plurality of parameter values of the model at an n^{th} time interval of the plurality of time intervals, wherein an is a second one of the plurality of parameter values of the model at the n^{th} time interval, and wherein bₙ is a third one of the plurality of parameter values of the model at the n^{th} time interval.

9. The method of claim 2, wherein the power loss value of the battery is determined
$$by ( {c}_{n} - {c}_{0} ) \{ {V}_{min} / ( 1 - {( - {c}_{n} / {a}_{n} )}^{\frac{1}{{b}_{n}}} ) \} ,$$
wherein cₙ is a first one of the plurality of parameter values of the model at an n^{th} time interval of the plurality of time intervals, wherein c₀ is the first one of the plurality of parameter values of the model at 0^{th} time interval of the plurality of time intervals, wherein Vₘᵢₙ is the minimum voltage cut-off of the battery, wherein aₙ is a second one of the plurality of parameter values of the model at the n^{th} time interval, and wherein bₙ is a third one of the plurality of parameter values of the model at the n^{th} time interval.

10. A battery management system to estimate an available power of a battery, comprising:
a memory; and
a processor coupled to the memory and configured to:
receive discharge data associated with the battery and a minimum voltage cut-off of the battery;
determine one or more discharge curves based on the discharging data;
estimate a model representing the one or more discharge curves;
calculate a plurality of parameter values of the model at a plurality of time intervals; and
estimate the available power of the battery based on the plurality of parameter values and the minimum voltage cut-off of the battery.

11. The battery management system of claim 10, wherein the processor is further configured to:
measure a resistive loss value of the battery and a capacity loss value of the battery based on the plurality of parameter values and the minimum voltage cut-off of the battery;
calculate a power loss value based on the resistive loss value and the capacity loss value; and
estimate the available power of the battery based on the power loss value.

12. The battery management system of claim 10, wherein the discharge data comprises any one or any combination of any two or more of a voltage, a current, a voltage rate, and a capacity of the battery.

13. The battery management system of claim 11, wherein the resistive loss value of the battery is current dependent and the capacity loss of the battery is current independent.

14. The battery management system of claim 10, wherein the model that represents the one or more curves is determined by ^{y=a}ₙ·x^{bn}+cₙ, and wherein aₙ, bₙ, and cₙ are the plurality of parameter values of the model at an n^{th} time interval of the plurality of time intervals, y is either one of a time and a capacity, and x is a normalized voltage axis.

15. The battery management system of claim 10, wherein the model representing the one or more discharge curves is proportional to a combination of aₙ, bₙ, and cₙ, and wherein aₙ, bₙ, and cₙ are the plurality of parameter values of the model at an n^{th} time interval of the plurality of time intervals.

16. The battery management system of claim 13, wherein the capacity loss value of the battery is determined by cₙ-c₀, wherein the resistive loss value of the battery is determined by
$${V}_{min} / ( 1 - {( - {c}_{n} / {a}_{n} )}^{\frac{1}{{b}_{n}}} ) ,$$
wherein Vₘᵢₙ is the minimum voltage cut-off of the battery, wherein c₀ is a first one of the plurality of parameter values at a 0^{th} time interval of the plurality of time intervals and cₙ is the first one of the plurality of parameter values of the model at an n^{th} time interval of the plurality of time intervals, wherein aₙ is a second one of the plurality of parameter values of the model at the n^{th} time interval, and wherein bₙ is a third one of the plurality of parameter values of the model at the n^{th} time interval.

17. The battery management system of claim 11, wherein the power loss value of the battery is determined by
$$( {c}_{n} - {c}_{0} ) \{ {V}_{min} / ( 1 - {( - {c}_{n} / {a}_{n} )}^{\frac{1}{{b}_{n}}} ) \} ,$$
wherein cₙ is a first one of the plurality of parameter values of the model at an n^{th} time interval of the plurality of time intervals, wherein c₀ is the first one of the plurality of parameter values of the model at 0^{th} time interval of the plurality of time intervals, wherein Vₘᵢₙ is the minimum voltage cut-off of the battery, wherein aₙ is a second one of the plurality of parameter values of the model at the n^{th} time interval, and wherein bₙ is a third one of the plurality of parameter values of the model at the n^{th} time interval.

18. The battery management system of claim 10, wherein the discharge data is collected at a plurality of time instances.
